(19) United States
(12) Patent Application Publication
(10) Pub. No.: US 2026/0040825 A1
(43) Pub. Date: Feb. 5, 2026

(54) BONDED BODY AND METHOD FOR PRODUCING BONDED BODY

(71) Applicants: NGK INSULATORS, LTD., Nagoya-shi (JP); NGK CERAMIC DEVICE CO., LTD., Komaki-shi (JP)

(72) Inventors: Takahiro YAMADERA, Nagoya-shi (JP); Ryuji TANABE, Inuyama-shi (JP); Masanari FUJITANI, Komaki-shi (JP)

(21) Appl. No.: 19/358,620

(22) Filed: Oct. 15, 2025

Related U.S. Application Data
(63) Continuation of application No. PCT/JP2023/045490, filed on Dec. 19, 2023.

(30) Foreign Application Priority Data
Apr. 26, 2023 (JP) 2023-072623

(51) Int. Cl. H10N 30/072; H10N 30/00; H10N 30/086

(52) U.S. Cl. CPC H10N 30/072; H10N 30/086; H10N 30/706

(57) ABSTRACT

A bonded body has a piezoelectric material substrate 11, a support substrate 13 bonded to the piezoelectric material substrate, and an outer peripheral processed part in which outer peripheral parts of the piezoelectric material substrate 11 and the support substrate 13 are inclined with respect to a main surface of the piezoelectric material substrate 11. The outer peripheral processed part includes a first inclined surface that is a surface that the piezoelectric material substrate 11 faces, and a second inclined surface that is on a plane extending from the first inclined surface toward the outer peripheral part and that is a surface that the support substrate 13 faces. Consequently, a bonded body in which no corners are formed on the outer peripheral part and fracture and cracks are less likely to occur in the outer peripheral part in subsequent steps, and a method for producing a bonded body are provided.

### CROSS REFERENCE TO RELATED INCORPORATION

This application is a continuation application of PCT/JP2023/045490, filed on Dec. 19, 2023, which claims the benefit of priority of Japanese Patent Application No. 2023-072623, filed on Apr. 26, 2023, the entire contents of which are incorporated herein by reference.

### TECHNICAL FIELD

The present invention relates to a bonded body and a method for producing a bonded body.

### BACKGROUND ART

For the purpose of realizing a high-performance semiconductor element, for example, a structure in which a piezoelectric material substrate and a support substrate are pasted together has been investigated. In recent years, a structure including an intermediate layer and a structure using a support substrate made of a difficult-to-process material have been proposed in order to realize a device with even higher performance. In order to realize this structure, it is necessary to paste both the piezoelectric material substrate and the support substrate, but when these substrates are pasted together, an area (unbonded part) that is not bonded is generated on the outer peripheral part. The unbonded part is generated due to the shape of the outer peripheral part before these substrates are pasted together. This shape is called sagging or roll-off. When an unbonded part occurs on the outer peripheral part, peeling is likely to occur during processing of the piezoelectric material. In addition, when peeling occurs, fragments are generated, and these fragments may damage the piezoelectric material. TO avoid this, a processing method for removing the unbonded part generated on the outer peripheral part has been proposed.

PTL 1 discloses a composite substrate for use in an acoustic wave device, the composite substrate including a support substrate, a piezoelectric substrate, and an adhesive layer that bonds the support substrate and the piezoelectric substrate. In this composite substrate, the piezoelectric substrate is formed such that, when the surface of the piezoelectric substrate that is bonded to the support substrate is defined as a first surface and the surface of the piezoelectric substrate opposite to the first surface is defined as a second surface, and when the first surface is projected onto the second surface in a direction perpendicular to the second surface, the first surface is inside the second surface. In other words, the outer peripheral surface of the piezoelectric substrate is formed such that the outer circumference becomes larger toward the outer peripheral side.

### CITATION LIST

### Patent Literature

PTL 1: WO 2011/013553

### SUMMARY OF INVENTION

### Technical Problem

However, while the conventional method can prevent problems caused by the unbonded part on the outer peripheral part, the outer peripheral part has a unique shape with corners on the substrates. As a result, fracture and cracks may occur in the outer peripheral part in subsequent steps, resulting in a decrease in yield.

The present invention aims to provide a bonded body in which no corners are formed on the outer peripheral part and fracture and cracks are less likely to occur in the outer peripheral part in subsequent steps, and also to provide a method for producing a bonded body.

### Solution to Problem

To solve the above problems, the present invention provides a bonded body having a piezoelectric material substrate, a support substrate bonded to the piezoelectric material substrate, and an outer peripheral processed part in which outer peripheral parts of the piezoelectric material substrate and the support substrate are inclined with respect to a main surface of the piezoelectric material substrate, wherein the outer peripheral processed part includes a first inclined surface that a surface of the piezoelectric material substrate faces, and a second inclined surface that is on a plane extending from the first inclined surface toward the outer peripheral part and that a surface of the support substrate faces.

The present invention also provides a method for producing a bonded body, the method including a bonding step of bonding a piezoelectric material substrate and a support substrate, and a polishing process step of polishing outer peripheral parts of the piezoelectric material substrate and the support substrate bonded to each other, wherein the polishing in the polishing process step is performed so as to form a first inclined surface that is inclined with respect to a main surface of the piezoelectric material substrate and is a surface that the piezoelectric material substrate faces, and a second inclined surface that is on a plane extending from the first inclined surface toward the outer peripheral part and is a surface that the support substrate faces.

### Advantageous Effects of Invention

According to the present invention, it is possible to provide a bonded body in which no corners are formed on the outer peripheral part and fracture and cracks are less likely to occur in the outer peripheral part in subsequent steps, and also to provide a method for producing a bonded body.

### BRIEF DESCRIPTION OF DRAWINGS

FIG. 1 shows a bonded body of the present embodiment.

FIG. 2 is a flow chart explaining the method for producing the bonded body.

FIGS. 3A to 3E show the states for each step shown in FIG. 2.

FIGS. 4A to 4D illustrate step 106 (grinding step) and step 107 (polishing process step) in FIG. 2.

FIGS. 5A and 5B are diagrams comparing polishing by the polishing process step of the present embodiment with polishing by a conventional method.

FIGS. 6A to 6D are diagrams comparing states before and after the grinding step and the polishing process step.

### DESCRIPTION OF EMBODIMENTS

Hereinafter, an embodiment of the present invention will be described in detail with reference to the appended drawings.

### <Explanation of Configuration of Bonded Body>

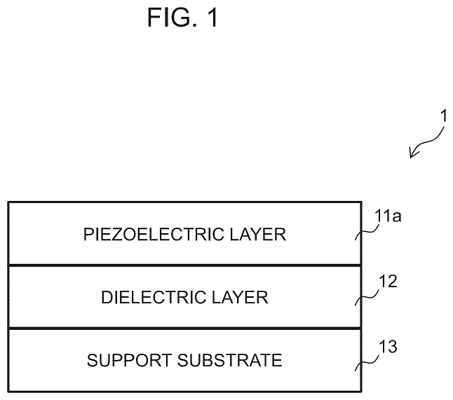

FIG. 1 shows a bonded body 1 of the present embodiment.

The bonded body 1 shown in the figure has a structure in which a piezoelectric layer 11a, a dielectric layer 12, and a support substrate 13 are laminated in this order from the top of the figure.

The piezoelectric layer 11a is made of a piezoelectric material. The piezoelectric material is selected depending on the application in which the bonded body 1 is to be used. Examples of the piezoelectric material include LiNbO₃ (LN) and LiTaO₃ (LT) but are not limited to these. Silicon (Si), gallium arsenide (GaAs), silicon carbide (SiC), gallium nitride (GaN), zinc oxide (ZnO), solid solution ceramics (PZT), and other materials may be selected as appropriate.

The dielectric layer 12 is disposed under the piezoelectric layer 11a. In the present embodiment, the dielectric layer 12 is mainly composed of SiO₂. In other words, the dielectric layer 12 can be said to be a SiO₂ film or a SiO₂ layer.

The support substrate 13 is a support for the entire bonded body 1. The support substrate 13 is bonded to the piezoelectric layer 11a with the dielectric layer 12 interposed therebetween. Any appropriate substrate may be used as the support substrate 13. The support substrate 13 may be made of a single crystal or a polycrystal. It may also be made of a metal.

The material constituting the support substrate 13 is preferably selected from the group consisting of silicon, sialon, sapphire, cordierite, mullite, glass, quartz, crystal, alumina, SUS, iron-nickel alloy (42 alloy), and brass. The thickness of the support substrate 13 is, for example, 0.2 mm to 1 mm, but any other appropriate thickness may be adopted.

The silicon may be single crystal silicon, polycrystal silicon, or high-resistance silicon. The support substrate 13 may also be SOI (Silicon on Insulator).

Typically, the sialon is a ceramic obtained by sintering a mixture of silicon nitride and alumina, and has a composition represented by, for example, Si_{6-w}Al_{w}O_{w}N_{8-w}. Specifically, sialon has a composition in which alumina is mixed into silicon nitride, and w in the formula indicates the mixing ratio of alumina. w is preferably 0.5 or more and 4.0 or less.

Typically, the sapphire is a single crystal having a composition of Al₂O₃, and the alumina is a polycrystalline body having a composition of Al₂O₃. The alumina is preferably translucent alumina.

Typically, the cordierite is a ceramic having a composition of 2MgO·2Al₂O₃·5SiO₂, and the mullite is a ceramic having a composition in the range of 3Al₂O₃·2SiO₂ to 2Al₂O₃·SiO₂.

### <Device>

The structure of the bonded body 1 shown in the figure can be used as the structure of various devices. Examples of devices include high-frequency devices, power semiconductors, semiconductor lasers, surface acoustic wave filters (SAW (Surface Acoustic Wave) filters), thin-film piezoelectric MEMS (Micro Electro Mechanical Systems), etc.

### <Description of Method for Producing Joint 1>

Next, a method for producing the bonded body 1 will be described.

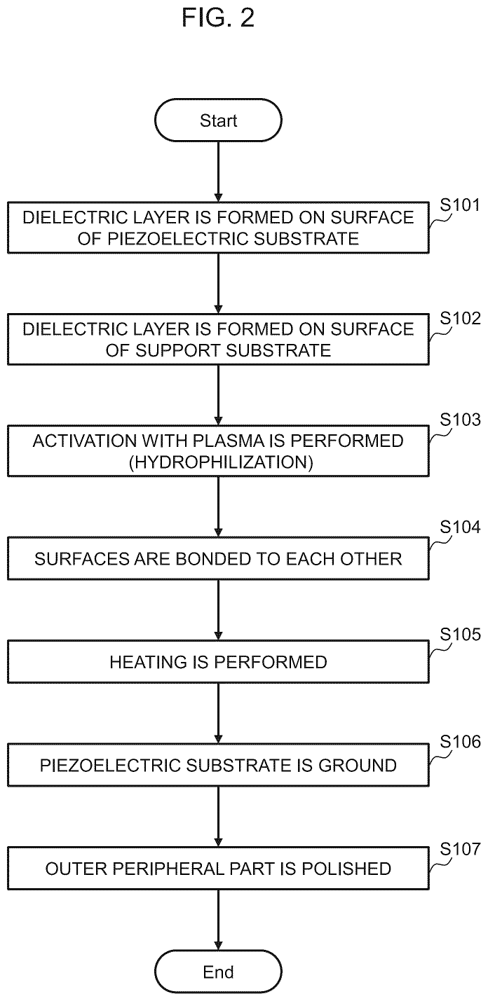

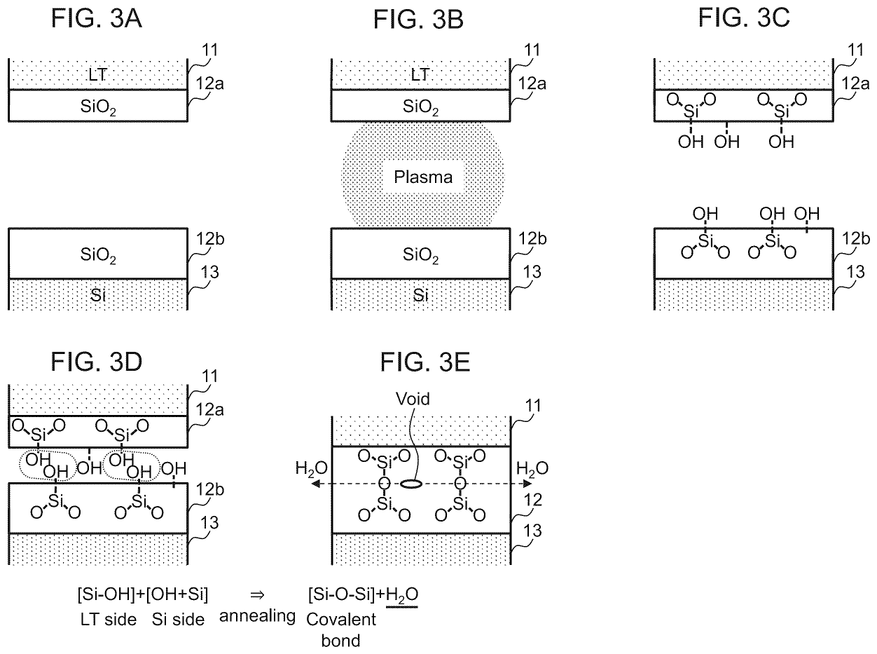

FIG. 2 is a flow chart explaining the method for producing the bonded body 1. Also, FIGS. 3A to 3E are diagrams showing the state for each of steps 101 to 105 shown in FIG. 2.

First, a piezoelectric material substrate 11 is prepared, and a dielectric layer 12a is formed on the surface of the piezoelectric material substrate 11 (step 101). Also, the support substrate 13 is prepared, and a dielectric layer 12b is formed on the surface of the support substrate 13 (step 102). Through steps 101 and 102, dielectric layers 12a and 12b are formed on the surfaces of the piezoelectric material substrate 11 and the support substrate 13 (dielectric layer forming steps: FIG. 3A). The order of steps 101 and 102 may be reversed, and the dielectric layers 12a and 12b may not be formed on the surfaces of the piezoelectric material substrate 11 and the support substrate 13 in steps 101 and 102. Here, the “surface” refers to the main surfaces of the piezoelectric material substrate 11 and the support substrate 13, not the side surfaces.

The dielectric layers 12a and 12b are mainly composed of SiO₂. The dielectric layers 12a and 12b are integrated by bonding in a subsequent step to form the dielectric layer 12 mainly composed of SiO₂. The dielectric layers 12a and 12b can be formed by reactive sputtering using a reactive sputtering device. Specifically, the piezoelectric material substrate 11 and the support substrate 13 are placed in the reactive sputtering device. A target made of silicon (Si) is also placed in the reactive sputtering device. Furthermore, argon (Ar) gas and oxygen radicals are introduced into the reactive sputtering device. The silicon that constitutes the target is then sputtered using a sputtering power supply to form a silicon film on the piezoelectric material substrate 11 and the support substrate 13, and the silicon film is then oxidized with oxygen radicals to form a silicon oxide (SiO₂) film. This allows dielectric layers 12a and 12b, mainly composed of SiO₂, to be formed on the surfaces of the piezoelectric material substrate 11 and the support substrate 13.

The dielectric layers 12a and 12b can also be polished and flattened, which improves the bonding strength when they are bonded in a subsequent step.

Next, the surfaces of the dielectric layers 12a and 12b are activated by plasma (step 103: activation step) (FIG. 3B). N₂ plasma can be used as the plasma. As a result, as shown in FIG. 3C, SiO₂ constituting the dielectric layers 12a and 12b is activated, and hydroxyl groups (OH groups) are generated as hydrophilic functional groups. Therefore, this step can also be considered as a hydrophilization step in which the surfaces of the dielectric layers 12a and 12b are made hydrophilic by plasma.

Furthermore, the surfaces of the dielectric layers 12a and 12b after the activation step are bonded together (step 104: bonding step) (FIG. 3D). The bonding is performed, for example, by bringing the surfaces of the dielectric layers 12a and 12b into contact with each other and pressing them together with a predetermined pressure. As a result, the piezoelectric material substrate 11 and the support substrate 13 are bonded with the dielectric layers 12a and 12b interposed therebetween.

In the above steps 101 and 102, where the dielectric layers 12a and 12b are not provided on the piezoelectric material substrate 11 and the support substrate 13, a method of irradiating the surfaces of the piezoelectric material substrate 11 and the support substrate 13 with a fast atom beam (hereinafter referred to as FAB) using an inert gas such as Ar as the atomic species for a predetermined time may be used to perform activation processing. After activating the piezoelectric material substrate 11 and the support substrate 13, they are bonded in the same manner as in the above bonding step.

Then, the bonded piezoelectric material substrate 11 and support substrate 13 are heated (step 105: heating step) (FIG. 3E). For example, the bonded piezoelectric material substrate 11 and support substrate 13 are placed in a heating device such as an oven, and heating is performed at a predetermined temperature and time. Hydroxyl groups generated on the surfaces of the dielectric layers 12a and 12b are covalently bonded by heating. The dielectric layers 12a and 12b are then integrated to become the dielectric layer 12. As a result, the piezoelectric material substrate 11 and the support substrate 13 are firmly bonded with the dielectric layer 12 interposed therebetween. At this time, the reaction [Si—OH]+[OH+Si]→[Si—O—Si]+H₂O occurs, generating water (H₂O). This water is released outside the dielectric layer 12.

The heating step can also be considered as a step (annealing step) for annealing the bonded piezoelectric material substrate 11 and support substrate 13.

Next, the piezoelectric material substrate 11 is ground to form a thin film (step 106: grinding step). This forms the piezoelectric layer 11a shown in FIG. 1. Grinding can be performed by a known method using a grinding machine.

The outer peripheral parts of the piezoelectric material substrate 11 and support substrate 13 are polished (step 107: polishing process step). Polishing can be performed by pressing a polishing film against the edge of the outer peripheral part of the bonded body 1 and rotating the bonded body 1 and the polishing film. The bonded body 1 can be produced by the above steps.

The grinding and polishing process steps are described in detail below.

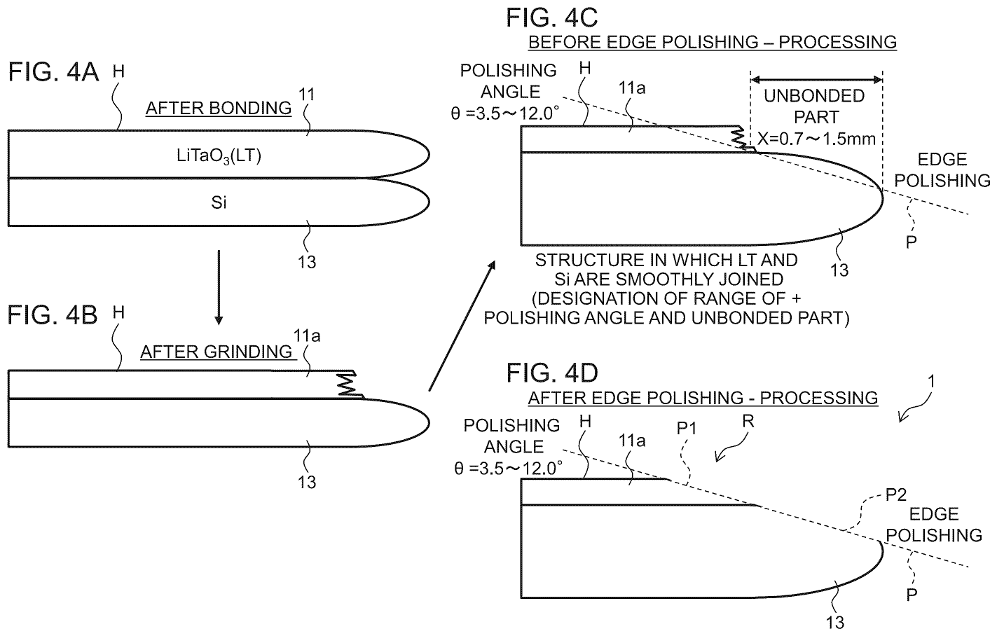

FIGS. 4A to 4D are diagrams explaining step 106 (grinding step) and step 107 (polishing process step) in FIG. 2.

FIG. 4A shows the piezoelectric material substrate 11 (in the illustrated example, a LiTaO₃ (LT) substrate) and the support substrate 13 (in the illustrated example, a Si substrate) after bonding through step 104 (bonding step) and step 105 (heating step). In this case, the dielectric layer 12 is not shown for the sake of convenience, but the dielectric layer 12 may be present.

FIG. 4B shows the piezoelectric material substrate 11 and the support substrate 13 after grinding in step 106 (grinding step). As shown in the figure, the piezoelectric material substrate 11 is thinned by grinding, and a piezoelectric layer 11a is formed.

FIG. 4C is a diagram that explains the state of FIG. 4B in more detail and shows the state before the polishing of step 107. This can be said to be the state before the edge polishing (polishing of the outer periphery) of the piezoelectric material substrate 11 and the support substrate 13. In this case, an unbonded part X, which is the area where the piezoelectric material substrate 11 and the support substrate 13 are not bonded, is 0.7 mm or more and 1.5 mm or less. In the present embodiment, polishing is performed to form a polishing surface P shown by the dotted line so that the unbonded part X is eliminated and the piezoelectric material substrate 11 (in the illustrated example, a LiTaO₃ (LT) substrate) and the support substrate 13 (in the illustrated example, a Si substrate) have a smoothly continuous structure, and an outer peripheral processed part R is formed in the outer peripheral part of the piezoelectric material substrate 11 and the support substrate 13. In practice, polishing is performed on the polishing surface P for which the polishing angle and the range of the unbonded part X are specified. Specifically, in the polishing process step, polishing is performed to form the polishing surface P having an angle of 3.5° or more and 12.0° or less with respect to the main surface H of the piezoelectric material substrate 11 and the support substrate 13. This can also be said to be polishing with a polishing angle θ=3.5° to 12.0° with respect to the main surface H of the piezoelectric material substrate 11 and the support substrate 13. In addition, in the polishing process step, the polishing is performed so that the length, when viewed from above, of a second inclined surface P2 where the support substrate 13 is exposed as a result of the piezoelectric material substrate 11 being polished away, which is the length from the center of the support substrate 13 toward the outer periphery, is 0.7 mm or more and 1.5 mm or less when viewed from above. As a result, the polishing surface P is formed that is composed of a first inclined surface P1 that is a facing surface of the piezoelectric material substrate 11 and the second inclined surface P2 that is a facing surface of the support substrate 13, and the first inclined surface P1 and the second inclined surface P2 are continuous.

Therefore, the polishing process step can be said to be a step of polishing performed to form the outer peripheral processed part R that is inclined with respect to the main surface H of the piezoelectric material substrate 11 and is composed of a first inclined surface P1 that is a facing surface of the piezoelectric material substrate 11 and a second inclined surface P2 that is a facing surface of the support substrate 13, the first inclined surface P1 and the second inclined surface P2 being continuous.

The angle is preferably 3.5° or more because it provides an area that can be sufficiently used as the bonded body 1. Also, the angle is preferably 12.00 or less because the risk of corner formation and of fracture or cracks occurring in the outer peripheral part in a subsequent step is suppressed. Also, where the length is 0.7 mm or more, it is sufficient to ensure a structure in which the piezoelectric material substrate 11 and the support substrate 13 are smoothly continuous. Also, the length of 1.5 mm or less is preferable because it provides an area that can be sufficiently used as the bonded body 1.

FIG. 4 D shows the state after the polishing process step of step 107. That is, this shows the state when the outer peripheral processed part R is formed after polishing at the polishing surface P specified in FIG. 4C. This can be said to be after the processing of edge polishing (polishing of the outer periphery) of the piezoelectric material substrate 11 and the support substrate 13.

Also, this can be said to be a configuration of the bonded body 1 that has the piezoelectric material substrate 11, the support substrate 13 bonded to the piezoelectric material substrate 11, and the outer peripheral processed part R processed so that the outer peripheral parts of the piezoelectric material substrate 11 and the support substrate 13 are inclined with respect to the main surface H of the piezoelectric material substrate 11, wherein the outer peripheral processed part R is composed of the first inclined surface P1 that is the facing surface of the piezoelectric material substrate 11 and the second inclined surface P2 that is the facing surface of the support substrate 13, and the first inclined surface P1 and the second inclined surface P2 are continuous.

Also, it can be said that in the configuration of the bonded body 1, the first inclined surface P1 and the second inclined surface P2 of the outer peripheral processed part R are inclined at an angle of 3.5° or more and 12.0° or less with respect to the main surface H of the piezoelectric material substrate 11.

Furthermore, the configuration of the bonded body 1 can be said to be such that the length of the second inclined surface P2 when viewed from above is 0.7 mm or more and 1.5 mm or less.

Where the dielectric layer 12 is present between the piezoelectric material substrate 11 and the support substrate 13, the first inclined surface P1 and the second inclined surface P2 will no longer be continuous. As the form also inclusive of this case, it can be said that the outer peripheral processed part R includes the first inclined surface P1 that is the facing surface of the piezoelectric material substrate 11, and the second inclined surface that is on a plane extending from the first inclined surface P1 toward the outer peripheral part and that is the facing surface of the support substrate 13. In other words, although the first inclined surface P1 and the second inclined surface P2 are not continuous, they are present on the same plane, and the surface of the dielectric layer 12 is present therebetween. The surface of the dielectric layer 12 is also present on this plane.

Furthermore, in this case, in the polishing process step, polishing can be also said to be performed to form the outer peripheral processed part R that is inclined with respect to the main surface H of the piezoelectric material substrate 11, and that is composed of the first inclined surface P1 that is the facing surface of the piezoelectric material substrate 11 and the second inclined surface P2 that is on a plane extending from the first inclined surface P1 toward the outer peripheral part and is a facing surface of the support substrate 13, and includes the first inclined surface P1 and the second inclined surface P2.

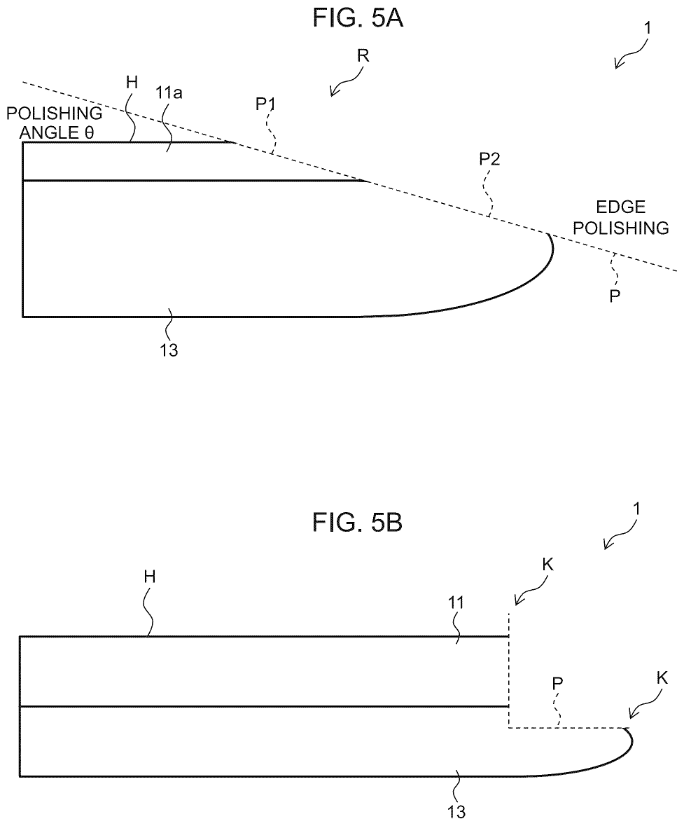

FIGS. 5A and 5B are diagrams comparing polishing by the polishing process step of the present embodiment with polishing by a conventional method.

Of these, FIG. 5A shows the bonded body 1 polished by the polishing process step of the present embodiment. In contrast, FIG. 5B shows the bonded body 1 polished by a conventional polishing method.

In FIG. 5A, by specifying the polishing surface P shown by the dotted line, a structure is obtained in which the first inclined surface P1 and the second inclined surface P2 forming this polishing surface P are continuous, and the piezoelectric layer 11a and the support substrate 13 are smoothly continuous.

In contrast, in FIG. 5B, the polishing surface P is shown by the dotted line, and in this case, two corners K are generated in the piezoelectric layer 11a and the support substrate 13.

In the bonded body 1 in FIG. 5B, the unbonded part X is eliminated, but the presence of the corners K makes it easy for fracture and cracks to occur in the outer peripheral part, for example, in the subsequent step of polishing the piezoelectric material substrate 11. As a result, the yield decreases. Meanwhile, in the bonded body 1 in FIG. 5A, the polishing surface P formed by polishing is inclined at a predetermined angle with respect to the main surface H. At this time, a structure in which the piezoelectric layer 11a and the support substrate 13 are smoothly continuous is obtained. As a result, the corners K are not formed, and fracture and cracks are less likely to occur in the outer peripheral part. In addition, in the bonded body 1 after edge polishing, the entire surface of the edge is not required to have the same angle, as long as the piezoelectric layer 11a on the support substrate 13 side and the support substrate 13 on the piezoelectric layer 11a side are continuously inclined. Furthermore, where a dielectric layer 12 is present between the piezoelectric layer 11a and the support substrate 13 side, the dielectric layer 12 may also be continuously inclined in the same manner.

### EXAMPLES

### Example 1

A 42Y-cut black LiTaO₃ (LT) substrate having a thickness of 0.25 mm and mirror-polished on both sides was prepared as the piezoelectric material substrate 11. A high-resistance (22 kΩ·cm) Si substrate with a thickness of 0.23 mm was prepared as the support substrate 13.

Next, a SiO₂ film was formed to a thickness of 0.5 μm as the dielectric layer 12a and the dielectric layer 12b on the LT substrate and the Si substrate (dielectric layer formation step), and the surfaces thereof were polished to about 0.1 μm and flattened by CMP (Chemical Mechanical Polishing).

The SiO₂ film surfaces of the LT substrate and the Si substrate were activated by N₂ plasma with a discharge output of 100 W (LT substrate side) and 65 W (Si substrate side), respectively (activation step), and then bonded (bonding step). The vacuum time in the bonding step was 120 sec.

To increase the bonding strength, the bonded substrates were placed in an oven at 130° C. and heated for 4 h (heating step). The LT surfaces of the bonded substrates removed from the oven were thinned to 2 μm by grinding (grinding step).

Then, a polishing film GC #2000 was brought into contact with the outer peripheral part, and polishing was performed for 120 sec to remove the unbonded part (polishing process step). The angle of the head fixing the polishing film was set to 79°. The film feed speed was 100 mm/min.

Finally, the LT surface was polished to 1 μm, and no abnormalities such as peeling or scratches on the LT substrate, chipping of the processed parts, or cracks occurred.

Then, when the finished shape of the outer periphery was checked, the inclination was 8.1°, the processing width (from the end of the Si substrate to the end of the LT substrate) was 786 μm (0.786 mm), and there were no unbonded parts. In other words, the polishing surface P had an angle of 8.1° with respect to the surfaces of the LT substrate and Si substrate.

### Example 2

The width of the unbonded part X is determined by the sagging of the wafer. When a bonded body is created using a commercially available wafer, the width of the unbonded part X is 0.8 mm to 1.2 mm.

In Example 2, a bonded body 1 with a width of the unbonded part X of 1.2 mm was used, and the unbonded part X was completely removed by setting the inclination angle, which is the polishing angle θ of the first inclined surface P1 and the second inclined surface P2, to 12° and polishing the edge.

### Example 3

In Example 3, the inclination angle was set to 13°, and the edge was polished. In this case, the unbonded part X was removed, but the range that can be used as a device was smaller than when the inclination angle was 12°.

### Example 4

In Example 4, a bonded body with a width of the unbonded part X of 0.8 mm was used, the inclination angle was set to 3°, and the edge was polished. In this case, processing was possible, but precise control was required.

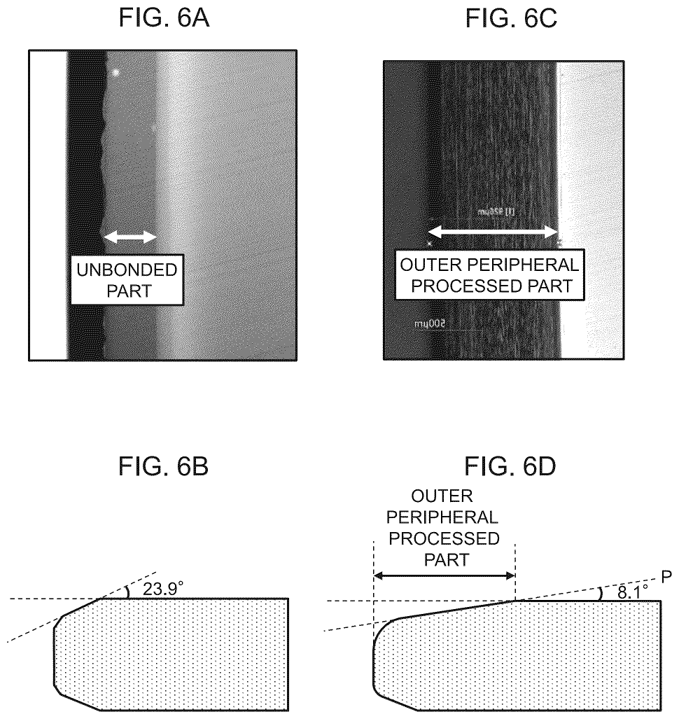

FIGS. 6A to 6D are diagrams comparing the states before and after the grinding and polishing process steps.

Among these, FIG. 6B is a diagram showing the state of the LT substrate and the Si substrate before the grinding step and the polishing process step as viewed from above, and FIG. 6B is a cross-sectional view of FIG. 6B. FIG. 6C is a diagram showing the state of the LT substrate and the Si substrate after the grinding step and the polishing process step as viewed from above, and FIG. 6D is a cross-sectional view of FIG. 6C. That is, FIGS. 6B and 6D are diagrams showing the LT substrate and the Si substrate as viewed from the same direction as in FIGS. 4 and 5.

FIG. 6A corresponds to the case illustrated by FIG. 4A, and there is an unbonded part (length 0.800 mm) where the LT substrate and the Si substrate are separated. As shown in FIG. 6B, the outer peripheral part of the LT substrate at this time had an angle of 23.9°.

FIG. 6C corresponds to the case illustrated by FIG. 4D and shows the state after polishing. In FIG. 6C, the polished area is shown as the outer peripheral processed part. Also, as shown in FIG. 6D, the outer peripheral part of the LT substrate at this time had an angle of 8.1° as described above.

The present embodiment has been described above, but the technical scope of the present invention is not limited to the scope described in the embodiment. It is clear from the claims that the technical scope of the present invention is also inclusive of embodiments obtained by various modifications or improvements of the above embodiment.

### REFERENCE SINGS LIST

1 Bonded body
11 Piezoelectric material substrate
11a Piezoelectric layer
12 12a 12b Dielectric layers
13 Support substrate
P Polished surface
P1 First inclined surface
P2 Second inclined surface
R Outer peripheral processed part

1. A bonded body comprising a piezoelectric material substrate, a support substrate bonded to the piezoelectric material substrate, and an outer peripheral processed part in which outer peripheral parts of the piezoelectric material substrate and the support substrate are inclined with respect to a main surface of the piezoelectric material substrate, wherein
the outer peripheral processed part includes a first inclined surface that a surface of the piezoelectric material substrate faces, and a second inclined surface that is on a plane extending from the first inclined surface toward the outer peripheral part and that a surface of the support substrate faces.

2. The bonded body according to claim 1, wherein the first inclined surface and the second inclined surface of the outer peripheral processed part are inclined at an angle of 3.5° or more and 12.0° or less with respect to the main surface of the piezoelectric material substrate.

3. The bonded body according to claim 1, wherein a length, when viewed from above, of the second inclined surface in a direction from a center of the support substrate toward the outer peripheral part, is 0.7 mm or more and 1.5 mm or less.

4. The bonded body according to claim 1, wherein the support substrate is made of Si.

5. The bonded body according to claim 4, wherein the piezoelectric material substrate and the support substrate are bonded, with a SiO₂ layer being interposed therebetween.

6. A method for producing a bonded body, the method comprising:
a bonding step of bonding a piezoelectric material substrate and a support substrate; and
a polishing process step of polishing outer peripheral parts of the piezoelectric material substrate and the support substrate bonded to each other, wherein
the polishing in the polishing process step is performed so as to form an outer peripheral processed part including a first inclined surface that is inclined with respect to a main surface of the piezoelectric material substrate and is a surface that the piezoelectric material substrate faces, and a second inclined surface that is on a plane extending from the first inclined surface toward the outer peripheral part and is a surface that the support substrate faces.

7. The method for producing a bonded body according to claim 6, further comprising, between the bonding step and the polishing process step, a grinding step of grinding the piezoelectric material substrate to form a thin film therefrom.

8. The method for producing a bonded body according to claim 6, further comprising
an activation step of activating respective surfaces of the piezoelectric material substrate and the support substrate by plasma, the surfaces being mainly composed of SiO₂, wherein
in the bonding step, the surfaces of the piezoelectric material substrate and the support substrate are bonded together, thereby bonding the piezoelectric material substrate and the support substrate, with a SiO₂ layer being interposed therebetween.

9. The method for producing a bonded body according to claim 8, further comprising a heating step of heating the piezoelectric material substrate and the support substrate that have been bonded to each other.
